(19) United States
(12) Patent Application Publication
(10) Pub. No.: US 2016/0141833 A1
(43) Pub. Date: May 19, 2016

(54) LASER DRIVER FOR DRIVING LASER DIODE

(71) Applicant: SUMITOMO ELECTRIC INDUSTRIES, LTD., Osaka (JP)

(72) Inventors: Akihiro MOTO, Yokohama-shi (JP); Keiji TANAKA, Yokohama-shi (JP)

(21) Appl. No.: 14/937,568

(22) Filed: Nov. 10, 2015

(30) Foreign Application Priority Data
Nov. 13, 2014 (JP) 2014-230920

(51) Int. Cl. H01S 5/042

(52) U.S. Cl. CPC H01S 5/042

(57) ABSTRACT

A laser driver to provide a shunt current to a laser diode is disclosed. The laser driver includes a first generator to generate a first signal in response to an input signal and a second signal generator to generate a second signal in response to the input signal. The first signal has first amplitude and a first rising transition that switches the laser diode from an ON state to an OFF state of the laser diode. The second signal has second amplitude smaller than the first amplitude and a second rising transition having a delay from the first rising transition. The laser driver further includes an output terminal to output the shunt current including the first signal and the second signal.

### BACKGROUND OF THE INVENTION

1. Field of the Invention

The present invention relates to a laser driver, in particular, a laser driver for driving a laser diode in a direct modulation system.

2. Background Arts

Some laser drivers have been developed for the direct to modulation system. For example, a laser driver which introduced a push-pull driving technique to provide a modulation current to a light emitting element is described in Japanese Patent Application Laid-Open No. 2012-109940.

Patent Literature 1: Japanese Patent Application Laid-Open No. 2012-109940.

### SUMMARY OF THE INVENTION

An aspect of the present application relates to a laser driver that comprises a first generator to generate a first signal in response to an input signal, a second signal generator to generate a second signal in response to the input signal, and an output terminal configured to output a shunt current to drive a laser diode. The first signal has first amplitude and a first rising transition. The first rising transition switches the laser diode from an on state to an off state of the laser diode. The second signal has second amplitude smaller than the first amplitude and a second rising transition having a delay from the first rising transition. The shunt current includes the first signal and the second signal.

### BRIEF DESCRIPTION OF THE DRAWINGS

The foregoing and other purposes, aspects and advantages will be better understood from the following detailed description of preferred embodiments of the invention with reference to the drawings, in which:

FIG. 1 is a circuit diagram of an optical transmitter according to a first embodiment of the present invention;

FIG. 2A shows an example of an electrical-to-optical response of a laser diode driven by a driving current of off level;

FIG. 2B shows an example of an electrical-to-optical response of a laser diode driven by a driving current of on level;

FIG. 3 shows an example of the low pass filter (LPF) shown in FIG. 1;

FIG. 4A shows an example of the bias circuit shown in FIG. 1;

FIG. 4B shows another example of the bias circuit shown in FIG. 1;

FIGS. 5A to 5E show examples of waveforms of a main signal, an input signal after passing through the low pass filter, a sub signal, a shunt current, and a driving current, respectively.

FIG. 6 shows an example of a driver IC including a laser driver shown in FIG. 1;

FIG. 7 is a circuit diagram of an optical transmitter including a laser driver according to a comparative example;

FIG. 8 shows an example of waveform of an optical output signal in the optical transmitter shown in FIG. 7;

FIG. 9 shows an example of waveform of a shunt current generated by the laser driver shown FIG. 1 and an example of waveform of a shunt current generated by the laser driver shown FIG. 7;

FIG. 10A shows an example of waveform of an optical output signal output from the optical transmitter shown in FIG. 7;

FIG. 10B shows an example of waveform of an optical output signal output from the optical transmitter shown in FIG. 1;

FIG. 11 is an equivalent circuit of a light emitting element (laser diode);

FIG. 12 is a circuit diagram of an optical transmitter according to a variation of the first embodiment of the present invention;

FIG. 13 is a circuit diagram of an optical transmitter according to another variation of the first embodiment of the present invention.

### DESCRIPTION OF THE PREFERRED EMBODIMENTS

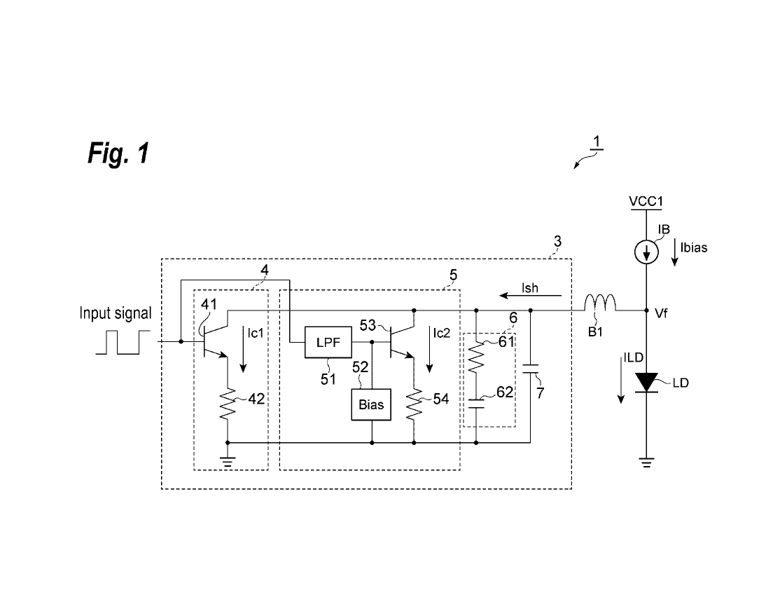

FIG. 1 shows a circuit diagram of an optical transmitter 1 including a laser driver 3 according to the first embodiment of the present application. The optical transmitter 1 includes a light emitting element (laser diode) LD, a bias current source IB, and a laser driver 3. The light emitting element LD is, for example, a semiconductor laser diode for the direct modulation system having a type of an edge emitting semiconductor laser. Specifically, a distributed feedback laser diode (DFB-LD) and/or a Fabry Perot laser diode (FP-LD) may be used as the semiconductor laser diode.

When such edge emitting semiconductor laser is driven by a laser driver in the direct modulation system, the optical output signal emitted from the edge emitting semiconductor laser shows some overshoots and undershoots at both of a 0 level (OFF level) and a 1 level (ON level) of waveform thereof. A relaxation oscillation of the edge emitting semiconductor laser causes such overshoots and undershoots. Frequency of the relaxation oscillation (relaxation oscillation frequency) depends on a driving current to drive the edge emitting semiconductor laser diode. The relaxation oscillation frequency becomes lower, when the driving current becomes small at the OFF level of the optical output signal.

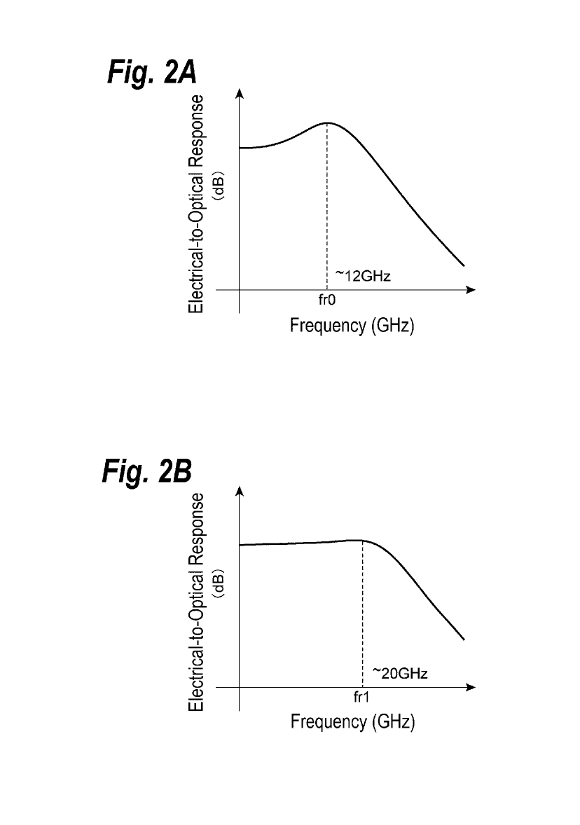

FIG. 2A shows an example of an electrical-to-optical response of a laser diode driven by a driving current for the OFF level. FIG. 2B shows an example of an electrical-to-optical response of a laser diode driven by a driving current for the ON level. In FIG. 2A, the frequency fr0 where the electrical-to-optical response shows a peak is about 12 GHz, which corresponds to the relaxation oscillation frequency of the OFF level. In FIG. 2B, the frequency fr1 where the electrical-to-optical response begins to decrease is about 20 GHz, which corresponds to the relaxation oscillation frequency of to the ON level. The relaxation oscillation frequency may be calculated from a rate equation, which is known as a basic formula to describe operation characteristics of a light emitting element. According to the rate equation, the relaxation oscillation frequency corresponds to a resonance frequency of modulation sensitivity of an optical output for a current input (driving current). The overshoots and undershoots of the optical waveform appear depending on the resonance frequency.

Referring back to FIG. 1, a cathode of the light emitting element LD is connected to the ground and an anode of the light emitting element LD is connected to a power supply line VCC1 through a bias current source IB. An automatic power control circuit APC (not drawn) adjusts a bias current Ibias provided to the light emitting element LD by the bias current source IB to maintain an average of intensity (power) of the optical output signal in a predetermined value. In addition, the anode of the light emitting element LD is connected with a laser driver 3 through a bonding wire B1. The laser driver 3 shunts a shunt current Ish. In such configuration, a driving current LD corresponding to the bias current Ibias minus the shunt current Ish is provided to the anode of the light emitting element LD. The anode of the light emitting element LD works as an input terminal of the light emitting element LD. The light emitting element LD outputs the optical output signal in response to the driving current LD.

The laser driver 3 is a laser driver for the direct modulation system, which provides the driving current ILD to the light emitting element LD based on a shunt driving technique. The laser driver 3 is, for example, a laser driver for a high-speed direct modulation system with a transmission rate of 25 Gbps or higher. The laser driver 3 directly modulates the light emitting element LD by turning on and off of the driving current ILD. The laser driver 3 generates the shunt current (output signal) Ish in response to an input signal. The shunt current Ish is a modulation signal to modulate the driving current ILD. A part of the bias current Ibias is bypassed as the shunt current Ish and the bypassed part flows into the laser driver 3 through the bonding wire B1. Accordingly, the rest of the bias current Ibias flows into the light emitting element LD as the driving current ILD. Therefore, the driving current ILD is equal to the bias current Ibias minus the shunt current Ish, namely Ibias-Ish. The waveform of the driving current ILD reverses the waveform of the shunt current Ish.

More specifically, the configuration of the laser driver 3 is explained below. The laser driver 3 includes a main signal generator (first generator) 4 and a sub signal generator (second generator) 5.

The main signal generator (first generator) 4 is a circuit to generate a main current (main signal) Ic1 to switch the light emitting element LD between the ON and OFF states in response to the input signal. The main signal generator 4 includes a transistor 41 (first transistor) and a resistor 42. The transistor 41 receives the input signal at a control terminal (base) thereof and output the main current Ic1 from one of current terminals thereof (collector). The transistor 41 is, for example, an NPN-type bipolar transistor. The base (control terminal) of the transistor 41 is connected to an input terminal of the laser driver 3. The emitter (the other of current terminals) of the transistor 41 is connected to the ground through the resistor 42. The collector (one of current terminals) of the transistor 41 is connected to the output terminal of the laser driver 3. In the configuration, when the input signal is fed to the base of the transistor 41, the transistor 41 is switched between the ON and OFF states according to voltage level of the input signal. While the transistor 41 is in the ON state, the collector current flows in the transistor 41 as the main current Ic1. While the transistor 41 is in the OFF state, the collector current (main signal) decreases to substantially zero.

The sub signal generator (second generator) 5 is a circuit to generate a sub current (second signal) Ic2 to slow a falling edge (falling transition) in the waveform of the driving current ILD from a middle of the falling transition, as described later. Here, an operation to slow a falling transition is equivalent to the operation to decrease a slope of the falling transition. The sub current Ic2 has the same polarity as the main current Ic1 and the amplitude of the sub current Ic2 is smaller than the amplitude of the main current Ic1. The sub current Ic2 in a DC magnitude thereof is smaller than that of the main current Ic1. The sub current Ic2 include asymmetrical pulses and a rise time larger (slower) than that of the main current Ic1. For one falling transition of the driving current ILD, the instant the sub current Ic2 begins to rise is delayed from the instant when the main current Ic1 begins to rise.

Here, the rise time of a signal is defined as a time required for the signal to move from a lower level to a higher level in waveform of the signal, taking a time in the horizontal axis and a physical parameter in the vertical axis. Along (large) rise time corresponds to a gradual slope (small differential coefficient) of a physical parameter of the signal. A long (large) fall time corresponds to a gradual slope (small differential coefficient) of a physical parameter of the signal. Here, when the Low level corresponds to 0% of amplitude and High level corresponds to 100% of amplitude, the rise time is specifically defined as a required time for a signal to move from 20% to 80% and the fall time is defined as a required time for the signal to move from 80% to 20%.

The sub signal generator (second generator) 5 includes a low pass filter (LPF) 51, a bias circuit 52, a transistor 53 (second transistor), and a resistor 54. The low pass filter 51 is a circuit to decrease high frequency components from the received input signal to decease a slope of a rising transition of the received input signal. An input terminal of the low pass to filter 51 is connected to the input terminal of the laser driver 3. An output terminal is connected to the base of the transistor 53.

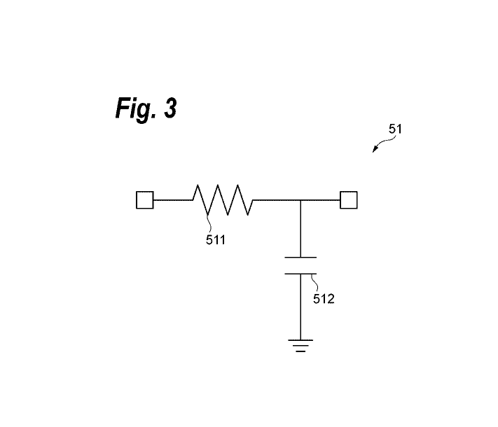

FIG. 3 shows an example of the low pass filter (LPF) 51 shown in FIG. 1. The low pass filter 51 includes a resistor 511 and a capacitor 512. One end of the resistor 511 works as an input terminal of the low pass filter 51 and the other end of the resistor 511 operates as an output terminal of the low pass filter 51. One end of the capacitor 512 is connecter to the other end of the resistor 511. The other end of the capacitor 512 is grounded. The resistor 511 has resistance of, for example, 300 Ohm. The capacitor has capacitance of, for example, 20 fF. The transistor 53 inherently has parasitic capacitance Cpi in the input thereof, which is dominant in comparison with the capacitor 512, so that the capacitor 512 preferably has capacitance small as possible. The resistance of the resistor 511 and the capacitance of the capacitor 512 may be determined based on the results of a large signal analysis (circuit simulation) of the optical transmitter 1. The laser driver 3, the light emitting element LD, and a parasitic element 7 are modeled for the large signal analysis by taking the relaxation oscillation frequency and other parameters of the light emitting element LD, the transmission rate, the interrelations among them, and so on into account.

The transistor 53 receives the input signal through the low pass filter 51 at a control terminal (base) thereof and outputs the sub signal Ic2 from one of current terminals thereof (collector). The transistor 53 is, for example, an NPN-type bipolar transistor. The base (control terminal) of the transistor 53 is connected to the output terminal of the low pass filter 51. The emitter (the other of current terminals) of the transistor 53 is grounded through the resistor 54. The collector (one of current terminals) of the transistor 54 is connected to the output terminal of the laser driver 3.

The resister 54 is used to set the amplitude of the sub signal Ic2 to a desired value. The amplitude of the sub signal Ic2 may be adjusted by trans-conductance gm of the transistor 53 and the resistance of the resistor 54. The trans-conductance gm of the transistor 53 depends on sizes of the transistor 53, for example, a gate length and a gate width in a case of the field effect transistor (FET).

The bias circuit 52 is a circuit to set the bias voltage of the control terminal (base) of the transistor 53. For example, the bias circuit 52 sets the bias voltage between 0.6 to 0.8 V. The shape of the waveform of the sub signal Ic2 depends on the bias voltage (base voltage) of the transistor 53. The base voltage is a sum of the input signal after passing through the low pass filter 51 and the bias voltage provided by the bias circuit 52. When the base voltage is lower than a forward voltage Vth2 of the p-n junction between the base and the emitter of the transistor 51, which is around 0.8 V, the transistor 53 becomes OFF and the sub signal Ic2 is ceased. When the base voltage is higher than the forward voltage Vth2, the transistor 53 turns on and flows the collector current therein, which corresponds to the sub signal Ic2. Therefore, the sub signal Ic2 has the waveform formed by a half-wave rectification of the input signal after passing through the low pass filter 51. A slice level of the half-wave rectification depends on the bias voltage. The bias voltage is set so that the sub signal Ic2 has a rising transition whose differential coefficient (momentary slope) gradually decreases as approaching the high level like a rounded corner. For example, the bias voltage is set so that the transistor 53 turns off while the signal is lower than the center level of the amplitude of the input signal after passing through the low pass filter 51.

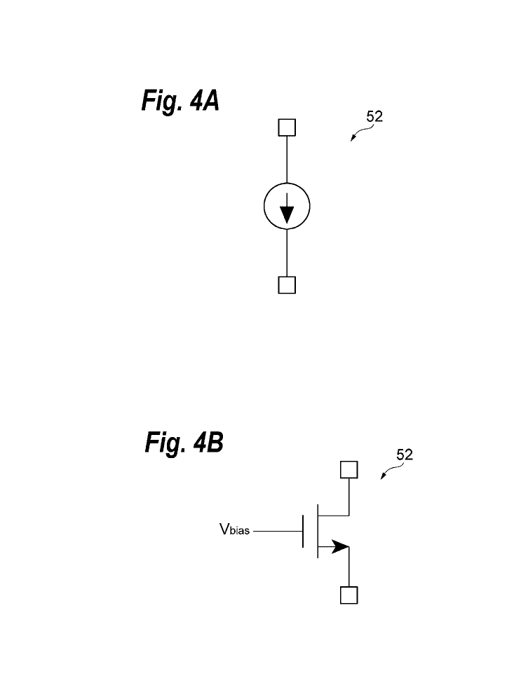

FIG. 4A shows an example of the bias circuit 52 shown in FIG. 1. FIG. 4B shows another example of the bias circuit 52 shown in FIG. 1. As shown FIG. 4A, the bias circuit 52 may be constituted of a current source. One end of the current source is connected to the base of the transistor 53 and the other end of the current source is connected to the ground. The bias circuit 52 constituted of an nMOSFET (n-type Metal-Oxide-Semiconductor Field-Effect Transistor) as shown in FIG. 4B provides 700 to 800 mV as the base voltage Vb2 of the transistor 53. The nMOSFET in the drain thereof is connected to the base of the transistor 53 and the source thereof is connected to the ground. The gate of the nMOSFET receives a bias voltage Vbias. The drain current of the nMOSFET becomes several hundreds of micro ampere to determine the bias voltage Vbias. Such a small drain current allows the nMOSFET to be formed in a small size. Parasitic capacitances may be reduced by downsizing the nMOSFET.

In the sub signal generator 5 described above, when the input signal is fed to the base of the transistor 53 through the low pass filter 51, the transistor 53 switches according to voltage level of the input signal. When the transistor 53 turns on, the collector of the transistor 53 generates (absorbs) a collector current as the sub signal Ic2. The bias circuit 52 in the sub signal generator 5 sets the bias voltage of the transistor 53 to a voltage level lower than the bias voltage of the transistor 41. The main signal Ic1 generated by the main signal generator 4 and the sub signal Ic2 generated by the sub signal generator 5 are superposed and output from an output terminal of the laser driver 3 to an anode of the light emitting element LD as the shunt current Ish.

The laser driver 3 further includes a suppression circuit 6. The suppression circuit 6 is a circuit to suppress a resonant peak caused by capacitance Cout attributed to a parasitic capacitor 7 and inductance Lbw of the bonding wire B1 connecting the output terminal of the laser driver 3 to the light emitting element LD. The suppression circuit 6 includes a resistor 61 and a capacitor 62. The resistor 61 and the capacitor 62 constitute a series circuit connected between the output terminal of the laser driver 3 and the ground.

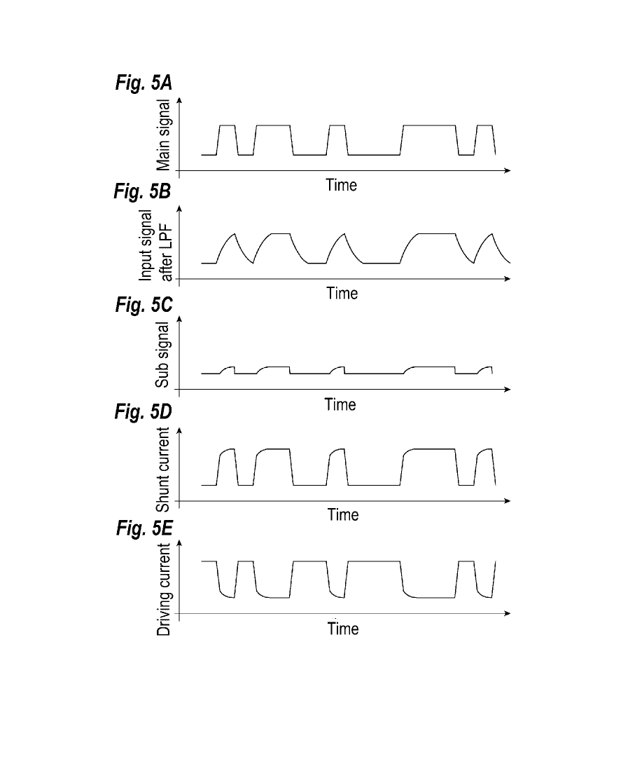

As referring FIGS. 5A to 5E, an operation of the laser driver 3 is described. FIGS. 5A to 5E show examples of waveforms to of the main signal Ic1; the input signal after passing through the low pass filter 51; the sub signal Ic2; the shunt current Ish; and the driving current ILD; respectively.

In the main signal generator 4, when the input signal is fed to the base (control terminal) of the transistor 41, the transistor 41 switches according to the voltage level of the input signal and generates (draws) the collector current as the main signal Ic1 shown in FIG. 5A.

In the sub signal generator 5, the input signal passes through the low pass filter 51. The input signal after passing through the low pass filter 51 has a longer rise time and a longer fall time in comparison with the original input signal before passing through the low pass filter 51, as shown in FIG. 5B. Specifically, in a rising transition from the Low level to the High level, the momentary slope (differential coefficients of the rising) is relatively large just after the sub signal begins to rise from the Low level, and gradually decreases when the sub signal Ic2 approaches the High level. Also, in a falling transition from the High level to the Low level, the momentary slope (differential coefficients of the falling) is relatively large (in an absolute value thereof) just after the sub signal begins to fall from the High level, and gradually decreases (in the absolute value thereof) when the sub signal approaches the Low level.

The input signal after passing through the low pass filter 51 is fed to the base of the transistor 53. The bias circuit 52 shifts the voltage level of the input signal fed to the base of the transistor 53 to a lower level, so that the transistor 53 turns off when the input signal is lower than a center value of the amplitude thereof, and the transistor 53 turns on when the input signal is higher than the center value, like performing a half-wave rectification. The collector of the transistor 53 outputs (shunts) a collector current as the sub signal Ic2 shown FIG. 5C.

The sub signal IC2 has the polarity same as the main to signal Ic1, but the waveform thereof seems to be generated from the input signal after passing through the low pass filter 51 by a half-wave rectification. The time at which the sub signal Ic2 begins to rise from the Low level is delayed from the time at which the main signal Ic1 begins to rise from the Low level. Also, the time at which the sub signal Ic2 begins to fall from the High level is delayed from the time at which the main signal Ic1 begins to fall from the High level. The delay in the rising transition is larger than the delay in the falling transition, and is smaller than one period of the transmission rate, for example, several pico-seconds.

The main signal Ic1 generated by the main signal generator 4 and the sub signal Ic2 generated by the sub signal generator 5 are added to each other to generate the shunt current Ish as shown in FIG. 5D. The shunt current Ish includes the sub signal Ic2 whose time to begin the rising transition is delayed from the time to being the rising transition of the main signal Ic1. The laser driver 3 shunts the shunt current Ish from the bias current Ibias. Accordingly, the driving current ILD is equal to the bias current Ibias minus the shunt current Ish, namely Ibias-Ish, as shown in FIG. 5E.

In the laser driver 3 described above, the transistor 41 and the transistor 53 are connected in parallel to the output terminal. The transistor 41 directly receives the input signal in the base thereof. The transistor 53 receives the input signal in the base thereof but through the low pass filter 51. The bias circuit 52 is connected to the base of the transistor 53. The bias circuit 52 sets the bias voltage to be applied to the base of the transistor 53 to a voltage level lower than the bias voltage applied to the base of the transistor 41. The transistor 41 subtracts (absorbs) the main signal Ic1 from the bias current Ibias, and the transistor 53 subtracts (absorbs) the sub signal Ic2 from the bias current Ibias concurrently with the transistor 41. Accordingly, the laser driver 3 modulates the driving current ILD by subtracting the shunt current Ish from the bias current Ibias. The shunt current Ish includes the main signal Ic1 and the sub current Ic2.

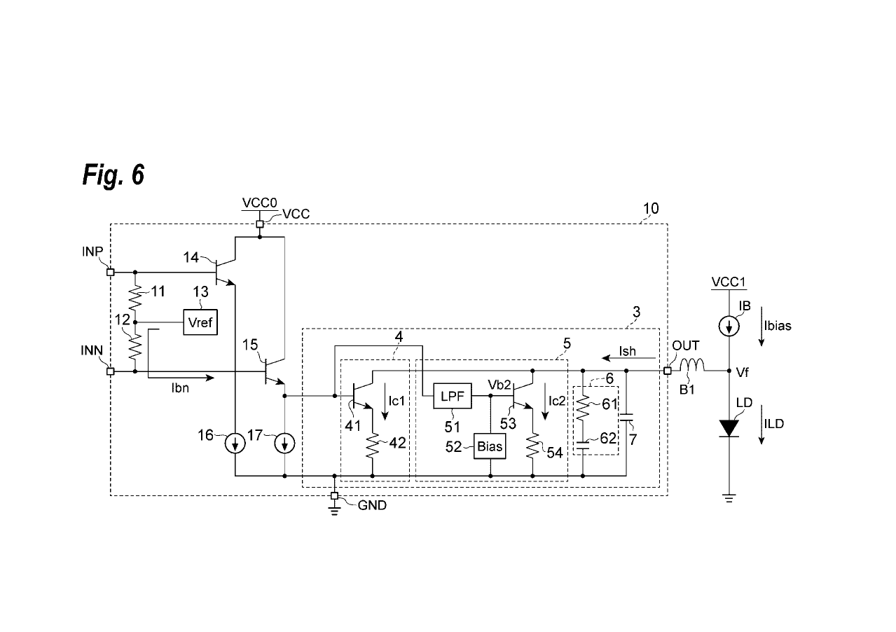

The above-mentioned laser driver is practically provided as a driver IC for a shunt driving system. FIG. 6 shows an example of a driver IC including the laser driver. The driver IC 10 is an integrated circuit to modulate the driving current ILD for driving the light emitting element LD in response to a differential input signal which is externally supplied to a pair of terminals, INP and INN, of the driver IC 10. The differential input signal constitutes of a positive-phase signal Vinp and a negative-phase signal Vinn whose phases are opposite to each other. The driver IC 10 includes the input terminals, INP and INN, an output terminal OUT, a power supply terminal Vcc, and a ground terminal GND. The input terminal INP receives the positive-phase signal Vinp and the input terminal INN receives the negative-phase signal Vinn. The output terminal is connected to an anode of the light emitting element LD through a bonding wire B1. The power supply terminal Vcc is connected to a power supply line Vcc0. The ground terminal GND is grounded (connected to a ground line).

The driver IC includes the laser driver 3, two resistors 11 and 12, a reference voltage generator 13, two transistors 14 and 15, and two current sources 16 and 17. The output terminal of the laser driver 3 is connected to the output terminal OUT. The ground potential is provided to the laser driver 3 through the ground terminal GND.

The resistors 11, 12 are termination resistors for the differential input signal. One end of the resistor 11 is connected to the input terminal INP and one end of the resistor 12 is connected to the input terminal INN. Respective other ends of the resistors 11, 12 are commonly connected to the reference voltage generator 13 and biased to a bias voltage Vref. The resistance R1 of the resistor 11 and the resistance R2 of the resistor 12 are, for example, 50 Ohm.

The transistor 14 is, which may be a type of, for example, to an NPN-type bipolar transistor, is connected to the input terminal INP in the base thereof, to the ground terminal GND through the current source 16 in the emitter, and to the power supply terminal Vcc in the collector. The transistor 15 is, which may be a type of, for example, an NPN-type bipolar transistor, is connected to the input terminal INN in the base, to the ground terminal GND through the current source 17 and the input terminal of the laser driver 3 in the emitter, and to the power supply terminal Vcc in the collector thereof.

In the driver IC 10 described above, an emitter follower, which is constituted of the transistor 14 and the current source 16, receives the positive-phase signal Vinp. Another emitter follower, which is constituted of the transistor 15 and the current source 17, receives the negative-phase signal Vinn. The output signal of the latter emitter follower that receives the negative-phase signal Vinn is provided to the laser driver 3 as an input signal. In the configuration, the base voltage Vb1 of the transistor 41 is determined by the following equation (1).

Vb1=Vref−R2×Ibn−Vben (1)

Where R2 is resistance of the resistor 12 and Ibn is a base current of the transistor 15 and Vben is a base-emitter voltage.

Advantages of the laser driver 3 is described below as referring to a comparative example.

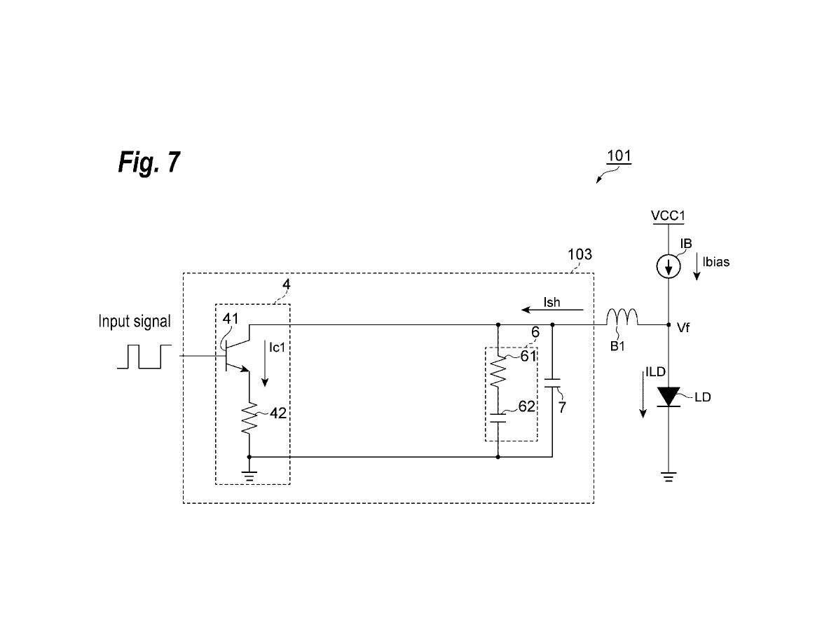

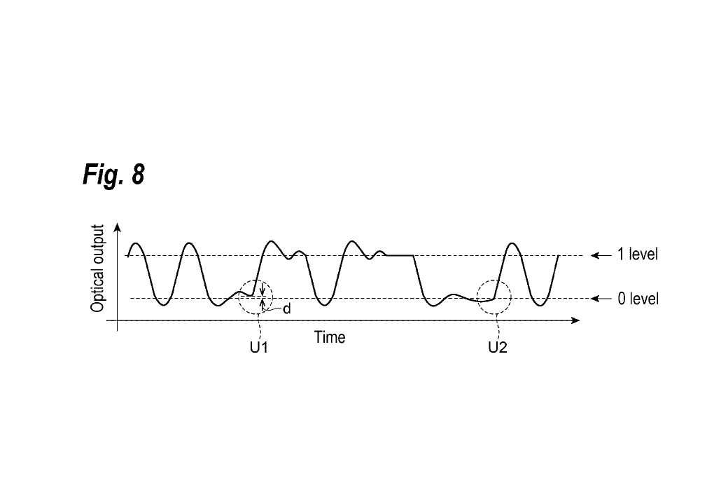

FIG. 7 is a circuit diagram of an optical transmitter including a laser driver according to a comparative example. FIG. 8 shows an example of a waveform of an optical output signal in the optical transmitter shown in FIG. 7;

As shown in FIG. 7, the optical transmitter 101 include a laser driver 103 instead of the laser driver 3, where the laser driver 103 does not provide the sub signal generator 5 that the optical transmitter 1 provides.

As shown in FIG. 8, the optical output signal of the optical transmitter 101 shows some overshoots and undershoots caused by the relaxation oscillations at 0 level (OFF level) and 1 level (ON level). The frequency of the relaxation oscillation corresponds to the relaxation oscillation frequency of a light emitting element LD depending on the driving current ILD at the 0 level and the 1 level. When the relaxation oscillation frequency is lower than the transmission rate of the optical output signal, some transitions between the 0 level and the 1 level occasionally occur before the relaxation oscillation disappears and other transitions occasionally occur after the relaxation oscillation disappears.

As referring to FIG. 2A, the relaxation oscillation frequency fr0 of the light emitting element LD is about 12 GHz for the 0 level (OFF level). As referring to FIG. 2B, the relaxation oscillation frequency fr0 of the light emitting element LD is about 20 GHz for the 1 level (ON level). The relaxation oscillation frequency is insufficient for a symbol rate of 25.78 Gbps, which is transmission rate of the 100 Gigabit Ethernet, and 27.95 Gbps, which is the transmission rate for OTU (Optical-channel Transport Unit) 4. Accordingly, the relaxation oscillation degrades the waveform of the optical output signal.

In the circled part U1 of the waveform shown in FIG. 8, a rising transition from the 0 level to the 1 level occurs after the 0 level is repeated twice (the 0 level continues for 2 bits). The transition in the circled part U1 occurs before the relaxation oscillation at the 0 level disappears. In the circled part U2 of the waveform shown in FIG. 8, another rising transition from the 0 level to the 1 level occurs after the 0 level is repeated thrice (the 0 level continues for 3 bits). The rising transition in the circled part U2 occurs after the relaxation oscillation at the 0 level disappears. The difference between the timing of the transition in the circled part U1 and the timing of the transition in the circled part U2 causes a pattern jitter in the waveform.

In the light emitting element LD, carrier consumption by photon in an active layer is delayed while the carrier decreases (corresponding to a falling transition of the optical output signal), and excessive carrier consumption occurs when the carrier stops the decreasing. This mechanism causes undershoots (just after the falling transition) in the waveform of the optical output signal. Then, excessive decrease of carrier density causes excessive decrease of carrier consumption by photon and carrier increased by current injection becomes in excess in comparison with the steady point (the 0 level) and brings about the relaxation oscillation like a swinging back. A gradual slope of a falling transition may restrain the relaxation oscillation, but such a slow transition maynot work for high-speed modulations. However, a steep slope with a partial gradual slope (only a lower part thereof is gradual, more specifically, differential coefficient dILD/dt is gradually decreased before the driving current ILD reaches the 0 level) to suppress the excessive decrease may restrain the relaxation oscillation.

The laser driver 3 generates the shunt current Ish to realize such a special slope by adding the sub signal Ic2 to the main signal Ic1. The main signal Ic1 controls the switching of the light emitting element LD between the 0 level and the 1 level. The sub signal Ic2 functions such that a differential coefficient dIc2/dt is gradually decreased before the driving current reaches the 0 level in a rising transition. Therefore, the rise time of the sub signal Ic2 is longer (larger) than the rise time of the main signal Ic1. The rising transition of the shunt current Ish is shaped by adding the rising transition of the sub signal Ic2 to the rising transition of the main signal Ic1, so that the slope of the shunt current holds steep in the middle of the transition and gradually becomes gentle before the shunt current reaches the High level (which corresponds to the Low level of the driving current). In other words, in the middle of the rising transition, the differential coefficient dIsh/dt (momentary slope) begins to decrease. The shunt driving system modulates the driving current ILD by subtracting the shunt current Ish from the bias current Ibias. The waveform of the driving current ILD reverses the waveform of the shunt current Ish. A gradual decrease of the differential coefficient (momentary slope) of the shunt current Ish from the middle of a rising transition allows the slope of the driving current ILD to be gradually decreased before the driving current ILD reaches the 0 level thereof from the middle of the falling transition. The driving current ILD with such a special slope enables to slow the rate of the carrier consumption from the middle of the falling transition and restrain the excessive decrease of the carriers. Therefore, the laser driver 3 reduces the relaxation oscillation in the 0 level of the optical output signal and prevents the waveform of the optical output signal from showing the undershoots, ringing in the 0 level, and the pattern jitters due to the relaxation oscillation.

Additionally, by decreasing the differential coefficient dIsh/dt (momentary slope) from the middle of the rising transition of the shunt current Ish, the differential coefficient dILD/dt from the middle of the falling transition of the driving current ILD may be decreased. If the whole slope of the falling transition of the driving current ILD is decreased, the optical output signal is unable to show a sufficient opening in the eye pattern. The laser driver 3 may prevent the eye pattern from being deteriorated.

In the laser driver 3, the transistor 41 outputs the main signal Ic1 in response to the input signal, while, the base of the transistor 41 directly receives the input signal. The transistor 53 outputs the sub signal Ic2 in response to the input signal after passing through the low pass filter 51, that is, the base of the transistor 53 receives the input signal through the low pass filter 51. The low pass filter reduces the high frequency components from the input signal, so that the rise time of the sub signal Ic2 is longer (larger) than the rise time of the main signal Ic1. The laser driver with the configuration described above enables the differential coefficient dIsh/dt (momentary slope) of the shunt current Ish to be gradually decreased from the middle of the rising transition, in particular, before the shunt current Ish reaches the 1 level thereof. Further, by adjusting the bias voltage supplied to the base of the transistor 53, the waveform of the sub signal Ic2 may be shaped based on the input signal after passing through the low pass filter 51, so that the lower part of the rising transition of the sub signal Ic2 shows a relatively steep slope and the upper part of the rising transition shows a relatively gradual slope to restrain the relaxation oscillation of the light emitting element LD.

As the amplitude of the sub signal Ic2 is smaller than the amplitude of the main signal Ic1, the ratio of the sub signal Ic2 to the shunt current becomes smaller than the ratio of the main signal Ic1 to the shunt current. In addition, the time at which the sub signal Ic2 begins to rise is delayed from the time at which the main signal Ic1 begins to rise. Therefore, the instant from which the differential coefficient dILD/dt of the driving current ILD begins to decrease may be close to the instant at which the driving current ILD reaches the 0 level. Here, the differential coefficient dILD/dt corresponds to the amount of decrease per a unit time (momentary slope) for the driving current ILD. Accordingly, the laser driver 3 may restrain degradation of the eye pattern of the optical output signal.

When the current source shown in FIG. 4A is used as the bias circuit 52, the input impedance of the sub signal generator 5 becomes substantially independent of the bias voltage provided to the base of the transistor 53 by the bias circuit 52. Therefore, influence of adjusting the bias voltage on the waveform of the sub signal Ic2 may be reduced.

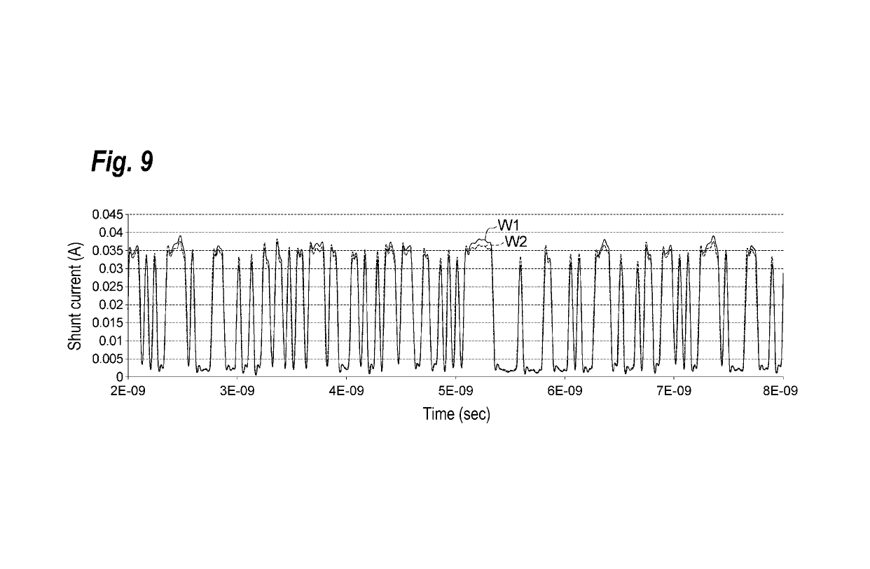

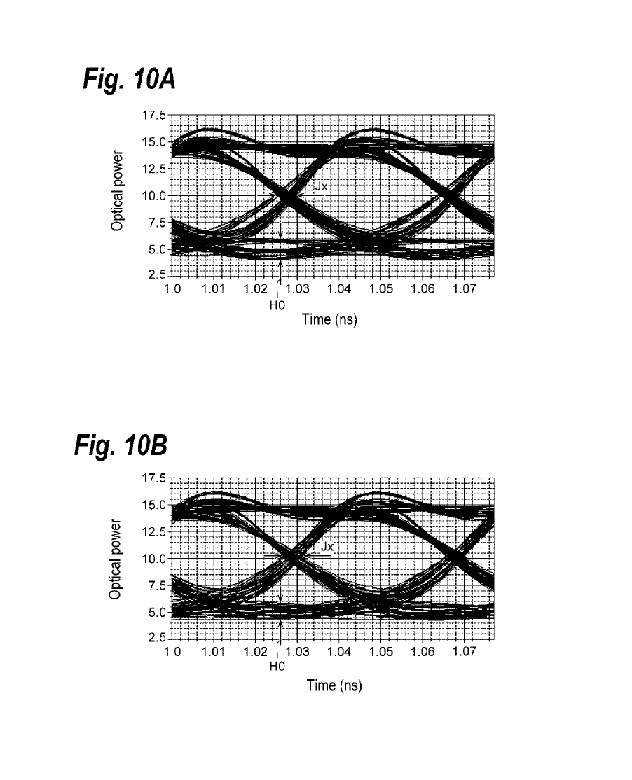

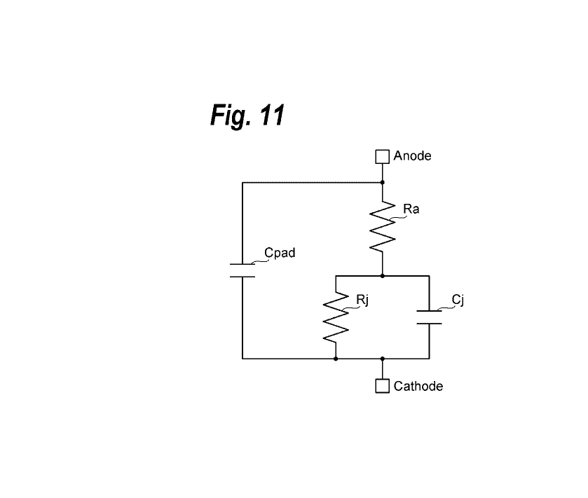

FIG. 9 shows an example of a waveform of a shunt current generated by the laser driver 3 shown FIG. 1 and an example of a waveform of a shunt current generated by the laser driver 103 shown FIG. 7. FIG. 10A shows an example of a waveform of an optical output signal output from the optical transmitter 101 shown in FIG. 7. FIG. 10B shows an example of a waveform of an optical output signal output from the optical transmitter 1 shown in FIG. 1. The examples of the waveforms in FIGS. 9, 10A, and 10B are the results of the circuit simulation. In the circuit simulation, the driver. IC 10 in FIG. 6 was used instead of the laser driver 3 in FIG. 1 for the configuration of the optical transmitter 1. Also, for the configuration of the optical transmitter 101, the driver IC 10 in FIG. 6 was used instead of the laser driver 3, but the sub signal generator 5 was removed from the driver IC 10. The equivalent circuit in FIG. 11 was used as the light emitting element LD, for both of the optical transmitters 1, 101.

In FIG. 9, W1 is the waveform of the shunt current Ish generated by the laser driver 3, and W2 is the waveform of the shunt current Ish generated by the laser driver 103. By comparing the waveform W1 with the waveform W2, it may be seen for W1 that the differential coefficient dIsh/dt (momentary slope) of the shunt current Ish is gradually decreased just before the shunt current Ish reaches the High level. In other words, the rising transition of the waveform W1 is relaxed compared with the rising transition of the waveform W2 before the shunt current reaches the High level. Therefore, the relaxation oscillation may be restrained by relaxing the rising transition near the High level as described above.

An advantage of the laser driver 1 on the optical output signal may be understood by comparing FIG. 10A with FIG. 10B. The width of a cross point Jx is 5.3 ps in FIG. 10A and 4.7 ps in FIG. 10B, showing improvement by about 11% (narrower width is better). Additionally, the thicknesses of the Low levels HO are 1.9 mW in FIG. 10A and 1.4 mW in FIG. 10B, respectively, with improvement of about 24%. The laser driver 3 shows the suppression in the undershoots and the ringing in the Low level and the decrease of the pattern jitter.

A laser driver according to the present invention is not limited to the laser driver according to the embodiment described above, and various modifications may be made. For example, the shunt current may include a main signal and a sub signal when the laser driver output the shunt current. Other variations having the equivalent functionality and behavior (operation) with the above-mentioned embodiments may be used as the main signal generator 4 and the sub signal generator 5.

A circuit configuration for generating the waveform of the driving current ILD shown in FIG. 5E is not limited to the circuit configuration according to the embodiment described above. For example, a circuit configuration to add a main signal having the waveform inverted from the waveform shown in FIG. 5A and a sub signal having the waveform inverted from the waveform shown in FIG. 5C may be used.

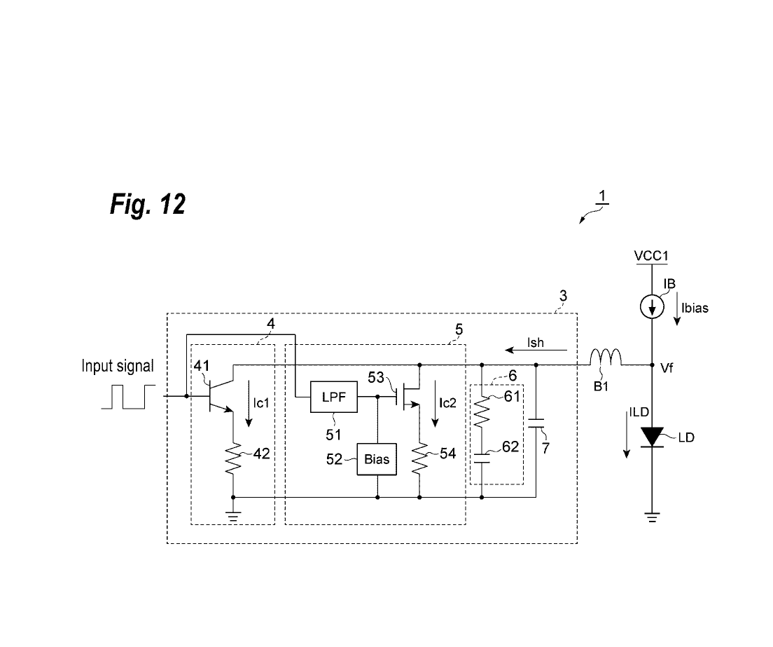

A transistor 53 in the sub signal generator 5 is not limited to the NPN-type bipolar transistor according to the embodiment described above. An nMOSFET may be used as the transistor 53 as shown in FIG. 12. The gate (control terminal) of the transistor 53 is connected to an output terminal of the low pass filter 51. The source (the other of current terminals) of the transistor 53 is grounded through the resistor 54. The drain (one of current terminals) of the transistor 53 is connected to an output terminal of the laser driver 3.

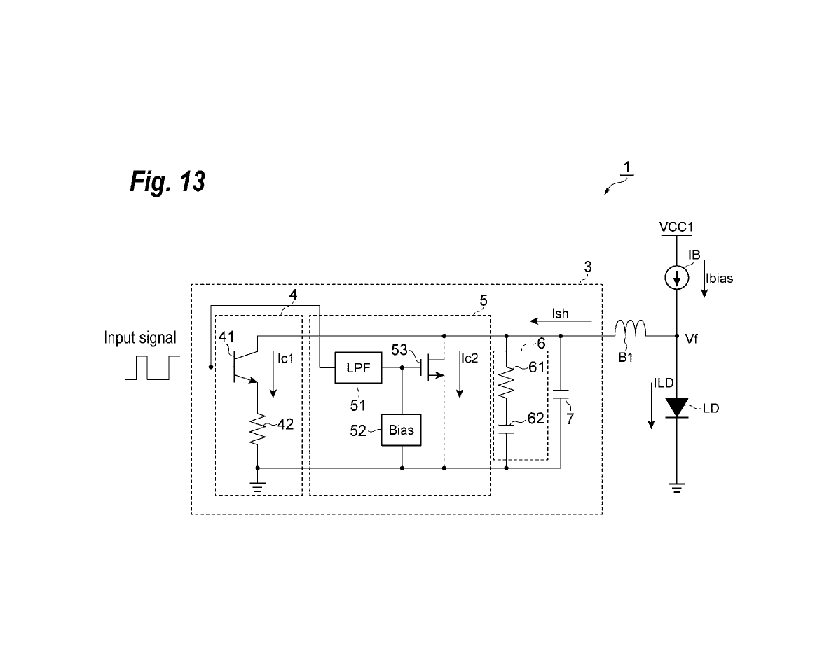

When an nMOSFET is used as the transistor 53, the source (the other of current terminals) of the nMOSFET may be directly grounded without the resistor 54 as shown in FIG. 13.

1. A laser driver to provide a shunt current to a laser diode, comprising:
a first generator to generate a first signal in response to an input signal, the first signal having first amplitude and a first rising transition that switches the laser diode from an ON state to an OFF state;
a second signal generator to generate a second signal in response to the input signal, the second signal having second amplitude smaller than the first amplitude and a second rising transition having a delay from the first rising transition; and
an output terminal configured to output the shunt current to an anode of the laser diode, the shunt current including the first signal and the second signal.

2. The laser driver of claim 1,
wherein the first signal has a first rise time, and
wherein the second signal has a second rise time longer than the first rise time.

3. The laser driver of claim 2,
wherein the first generator includes a first transistor configured to receive the input signal at a control terminal thereof and output the first signal from a current terminal thereof, and
wherein the second generator includes a second transistor and a low pass filter, the second transistor being configured to receive the input signal at a control terminal thereof through the low pass filter and output the second signal from a current terminal thereof, the low pass filter being configured to reduce high frequency components from the input signal.

4. The laser driver of claim 3,
wherein the second generator further includes a bias circuit configured to provide a bias voltage to the control terminal of the second transistor.

5. The laser driver of claim 4,
wherein the bias circuit includes a current source.

6. The laser driver of claim 1,
wherein the laser diode is configured to externally receive a bias current and be driven by a driving current generated by subtracting the shunt current from the bias current.
